(19) United States
(12) Patent Application Publication
(10) Pub. No.: US 2009/0104719 A1
(43) Pub. Date: Apr. 23, 2009

(54) Plasma Doping System with In-Situ Chamber Condition Monitoring

(75) Inventors: Atul Gupta, Beverly, MA (US); Timothy Miller, Ipswich, MA (US); Harold M. Persing, Westbrook, ME (US); Daniel Distaso, Merrimac, MA (US); Vikram Singh, North Andover, MA (US)

Correspondence Address: RAUSCHENBACH PATENT LAW GROUP, LLC, P.O. BOX 387, BEDFORD, MA, 01730, US

(73) Assignee: VARIAN SEMICONDUCTOR EQUIPMENT ASSOCIATES, INC., Gloucester, MA (US)

(21) Appl. No.: 11/877,312

(22) Filed: Oct. 23, 2007

(51) Int. Cl. H01L 21/66

(52) U.S. Cl. 438/7; 438/16; 257/E21.521

(57) ABSTRACT

A method of in-situ monitoring of a plasma doping process includes generating a plasma comprising dopant ions in a chamber proximate to a platen supporting a substrate. A platen is biased with a bias voltage waveform having a negative potential that attracts ions in the plasma to the substrate for plasma doping. A dose of ions attracted to the substrate is measured. At least one sensor measurement is performed to determine the condition of the plasma chamber. In addition, at least one plasma process parameter is modified in response to the measured dose and in response to the at least one sensor measurement.

The section headings used herein are for organizational purposes only and should not to be construed as limiting the subject matter described in the present application.

### BACKGROUND OF THE INVENTION

Plasma processing has been widely used in the semiconductor and other industries for many decades. Plasma processing is used for tasks such as cleaning, etching, milling, and deposition. More recently, plasma processing has been used for doping. Plasma doping is sometimes referred to as PLAD or plasma immersion ion implantation (PIII). Plasma doping systems have been developed to meet the doping requirements of state-of-the-art electronic and optical devices.

Plasma doping systems are fundamentally different from conventional beam-line ion implantation systems that accelerate ions with an electric field and then filter the ions according to their mass-to-charge ratio to select the desired ions for implantation. In contrast, plasma doping systems immerse the target in a plasma containing dopant ions and bias the target with a series of negative voltage pulses. The term “target” is defined herein as the workpiece being implanted, such as a substrate or wafer being ion implanted. The negative bias on the target repels electrons from the target surface thereby creating a sheath of positive ions. The electric field within the plasma sheath accelerates ions toward the target thereby implanting the ions into the target surface.

Conventional beam-line ion implantation systems that are widely used in the semiconductor industry have excellent process control and also excellent run-to-run uniformity. Conventional beam-line ion implantation systems provide highly uniform doping across the entire surface of state-of-the art semiconductor substrates. Plasma doping systems for the semiconductor industry must also have a very high degree of process control. However, in general, the process control of plasma doping systems is not as good as conventional beam-line ion implantation systems.

### BRIEF DESCRIPTION OF THE DRAWINGS

The invention, in accordance with preferred and exemplary embodiments, together with further advantages thereof, is more particularly described in the following detailed description, taken in conjunction with the accompanying drawings. The drawings are not necessarily to scale, emphasis instead generally being placed upon illustrating principles of the invention.

FIG. 1 illustrates a schematic diagram of a plasma doping system that includes in-situ chamber monitoring according to the present invention.

FIG. 2 illustrates a flow chart of a method of in-situ monitoring and process control of a plasma doping process according to the present invention.

FIG. 3 illustrates a flow chart of a method of in-situ monitoring of a plasma doping process that triggers a maintenance event and or termination of the plasma doping process according to the present invention.

### DETAILED DESCRIPTION

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

It should be understood that the individual steps of the methods of the present invention may be performed in any order and/or simultaneously as long as the invention remains operable. Furthermore, it should be understood that the apparatus and methods of the present invention can include any number or all of the described embodiments as long as the invention remains operable.

The present teachings will now be described in more detail with reference to exemplary embodiments thereof as shown in the accompanying drawings. While the present teachings are described in conjunction with various embodiments and examples, it is not intended that the present teachings be limited to such embodiments. On the contrary, the present teachings encompass various alternatives, modifications and equivalents, as will be appreciated by those of skill in the art. Those of ordinary skill in the art having access to the teachings herein will recognize additional implementations, modifications, and embodiments, as well as other fields of use, which are within the scope of the present disclosure as described herein. For example, although the present invention is described in connection with a plasma doping system, the methods and apparatus for monitoring chamber conditions applies to many other types of plasma processing systems.

Three dimensional device structures are now being developed to increase the available surface area of ULSI circuits as well as to extend the device scaling to sub 65 nm technology nodes. For example, three dimensional trench capacitors used in DRAMs, and numerous types of devices using vertical channel transistors, such as the FinFETs (Double or Triple gate) and recessed channel array transistors (RCAT) are being developed in research laboratories. Many of these three dimensional devices require very precise control of the plasma doping process. In addition, numerous other types of modern electronic and optical devices and nanotechnology microstructures require very precise control of the plasma doping process.

The present invention relates to methods and apparatus for monitoring plasma chamber conditions during plasma processing. In particular, the present invention relates to methods and apparatus for in-situ monitoring of plasma chamber conditions during plasma processing. The term “in-situ monitoring” refers to monitoring while performing the plasma processing.

The repeatability of a plasma doping process correlates directly with the repeatability of the state of the plasma. Some plasma parameters which determine the state of the plasma include the plasma composition, ion density, electron and ion temperatures, and plasma potential. These plasma parameters are strongly influenced by the conditions of the plasma chamber walls that are in direct contact with the plasma. The conditions of the plasma chamber walls tend to drift over time because they are constantly bombarded with ions and neutrals generated in the plasma. In addition, the fraction of ions in the plasma and, therefore, the ion density or ion flux also tends to drift over time for various reasons. The drift in ion density or ion flux causes the ion implantation dose to drift over time, which makes the plasma doping process less repeatable.

Thus, the stability and repeatability of a plasma doping process is dependent upon the physical conditions of the plasma chamber. In addition, the ion density tends to drift over time causing time variations in the implantation dose, which makes the plasma doping process less repeatable. In order to achieve very precise control of a plasma doping process, the user must be able to accurately monitor the condition of the plasma chamber and also the ion implantation dose being applied to the substrate during processing. In other words, the user must perform real time in-situ measurements of the plasma chamber condition and the ion implantation dose.

Therefore, it is desirable to have real time in-situ measurements of the plasma conditions. In addition, it is desirable to have active dosimetery, which takes real time in-situ measurement of the ion flux or the ion implantation dose. A plasma doping system according to the present invention uses various sensors to determine the condition of the plasma chamber. For example, a plasma doping system according to the present invention can include optical emission sensors, secondary electron emission sensors, film deposition monitors, and residual gas analyzers to determine the condition of the plasma chamber. Such sensors are sometimes used in plasma deposition and etching systems. In addition, a plasma doping system according to the present invention can include instruments that monitor RF impedance and plasma floating potential to determine the condition of the plasma chamber.

The apparatus and methods of the present invention combine real time in-situ measurements of the plasma conditions with real time in-situ measurements of ion flux or ion implantation dose. In some embodiments, electrical signals generated from the real time in-situ measurements of the plasma conditions and the real time in-situ measurements of the ion flux or ion implantation dose are used to trigger a corrective action, which brings the process back within predetermined control limits. For example, the corrective action can be a change in the process parameters. In many embodiments, the corrective actions are triggered in real time. In addition, the electrical signals generated from the real time, in-situ measurements of the plasma conditions and the real time, in-situ measurements of ion flux or ion implantation dose can be used to trigger a maintenance event and/or the termination of plasma doping process.

Obtaining such real time in-situ measurements of the plasma chamber conditions is desirable because these measurements can be used to change the process conditions in order to achieve tighter process control, which is very important for many plasma processes, such as plasma doping processes. In addition, obtaining such real time in-situ measurements of the plasma chamber conditions is desirable because access to such measurements can significantly reduce the amount of routine maintenance performed in these systems.

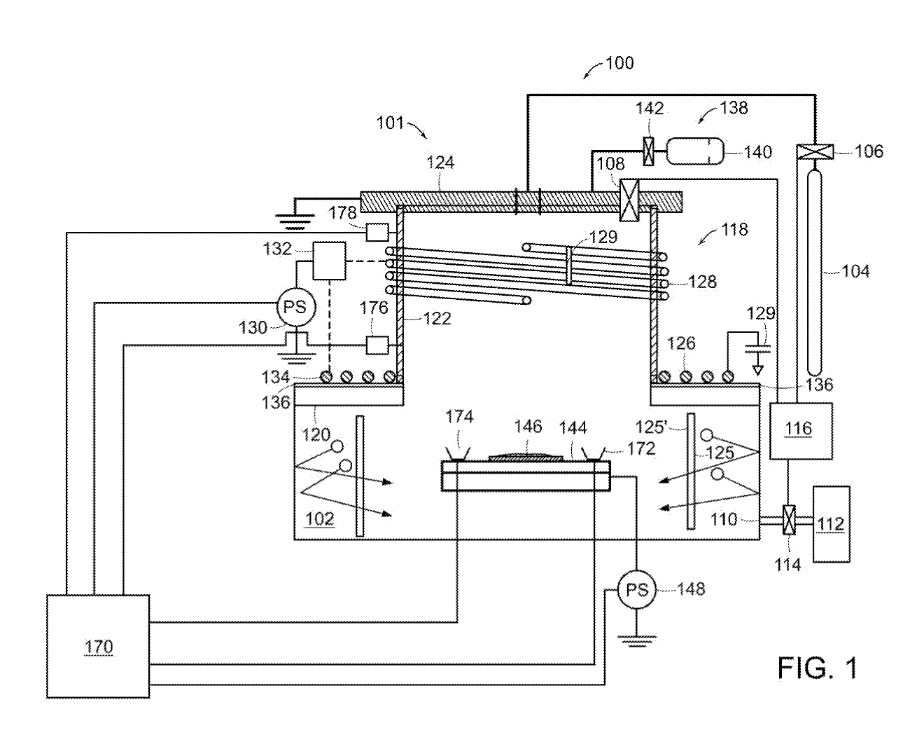

FIG. 1 illustrates a schematic diagram of a plasma doping system 100 that includes the in-situ chamber condition monitoring of the present invention. A similar plasma doping system is described in U.S. patent application Ser. No. 10/905,172, filed on Dec. 20, 2004, entitled “RF Plasma Source with Conductive Top Section,” which is assigned to the present assignee. The entire specification of U.S. patent application Ser. No. 10/905,172 is incorporated herein by reference. The plasma source 101 shown in the plasma doping system 100 is well suited for plasma doping applications because it can provide a highly uniform ion flux and because it efficiently dissipates heat generated by secondary electron emissions.

More specifically, the plasma doping system 100 includes a plasma chamber 102 that contains a process gas supplied by an external gas source 104. The process gas typically contains a dopant species that is diluted in a dilution gas. The external gas source 104, which is coupled to the plasma chamber 102 through a proportional valve 106, supplies the process gas to the chamber 102. In some embodiments, a gas baffle is used to disperse the gas into the plasma source 101. A pressure gauge 108 measures the pressure inside the chamber 102. An exhaust port 110 in the chamber 102 is coupled to a vacuum pump 112 that evacuates the chamber 102. An exhaust valve 114 controls the exhaust conductance through the exhaust port 110.

A gas pressure controller 116 is electrically connected to the proportional valve 106, the pressure gauge 108, and the exhaust valve 114. The gas pressure controller 116 maintains the desired pressure in the plasma chamber 102 by controlling the exhaust conductance and the process gas flow rate in a feedback loop that is responsive to the pressure gauge 108. The exhaust conductance is controlled with the exhaust valve 114. The process gas flow rate is controlled with the proportional valve 106.

The chamber 102 has a chamber top 118 including a first section 120 formed of a dielectric material that extends in a generally horizontal direction. A second section 122 of the chamber top 118 is formed of a dielectric material that extends a height from the first section 120 in a generally vertical direction. The first and second sections 120, 122 are sometimes referred to herein generally as the dielectric window. It should be understood that there are numerous variations of the chamber top 118. For example, the first section 120 can be formed of a dielectric material that extends in a generally curved direction so that the first and second sections 120, 122 are not orthogonal as described in U.S. patent application Ser. No. 10/905,172, which is incorporated herein by reference. In other embodiment, the chamber top 118 includes only a planer surface.

The shape and dimensions of the first and the second sections 120, 122 can be selected to achieve a certain performance. For example, one skilled in the art will understand that the dimensions of the first and the second sections 120, 122 of the chamber top 118 can be chosen to improve the plasma uniformity. In one embodiment, a ratio of the height of the second section 122 in the vertical direction to the length across the second section 122 in the horizontal direction is adjusted to achieve more uniform plasmas. For example, in one particular embodiment, the ratio of the height of the second section 122 in the vertical direction to the length across the second section 122 in the horizontal direction is in the range of 1.5 to 5.5.

The dielectric materials in the first and second sections 120, 122 provide a medium for transferring the RF power from the RF antenna to the plasma inside the chamber 102. In one embodiment, the dielectric material used to form the first and second sections 120, 122 is a high purity ceramic material that is chemically resistant to the process gases and that has good thermal properties. For example, in some embodiments, the dielectric material is 99.6% Al₂O₃ or AlN. In other embodiments, the dielectric material is Yittria and YAG.

A lid 124 of the chamber top 118 is formed of a conductive material that extends a length across the second section 122 in the horizontal direction. In many embodiments, the conductivity of the material used to form the lid 124 is high enough to dissipate the heat load and to minimize charging effects that results from secondary electron emission. Typically, the conductive material used to form the lid 124 is chemically resistant to the process gases. In some embodiments, the conductive material is aluminum or silicon.

The lid 124 can be coupled to the second section 122 with a halogen resistant O-ring made of fluoro-carbon polymer, such as an O-ring formed of Chemrz and/or Kalrex materials. The lid 124 is typically mounted to the second section 122 in a manner that minimizes compression on the second section 122, but that provides enough compression to seal the lid 124 to the second section. In some operating modes, the lid 124 is RF and DC grounded as shown in FIG. 1. In addition, in some embodiments, the lid 124 comprises a cooling system that regulates the temperature of the lid 124 and the surrounding area in order to dissipate the heat load generated during processing. The cooling system can be a fluid cooling system that includes cooling passages in the lid 124 which circulate a liquid coolant from a coolant source.

In some embodiments, the chamber 102 includes a liner 125 that is positioned to prevent or greatly reduce metal contamination by providing line-of-site shielding of the inside of the plasma chamber 102 from metal sputtered by ions in the plasma striking the inside metal walls of the plasma chamber 102. Such liners are described in U.S. patent application Ser. No. 11,623,739, filed Jan. 16, 2007, entitled “Plasma Source with Liner for Reducing Metal Contamination,” which is assigned to the present assignee. The entire specification of U.S. patent application Ser. No. 11/623,739 is incorporated herein by reference. In some embodiments, the plasma chamber liner 125 includes a temperature controller. In one particular embodiment, the temperature controller maintains the temperature of the liner 125 at a relatively low temperature that is sufficient for absorption of a film layer that generates neutrals during film desorption according to the present invention.

A RF antenna is positioned proximate to at least one of the first section 120 and the second section 122 of the chamber top 118. The plasma source 101 in FIG. 1 illustrates two separate RF antennas that are electrically isolated from one another. However, in other embodiments, the two separate RF antennas are electrically connected. In the embodiment shown in FIG. 1, a planar coil RF antenna 126 (sometimes called a planar antenna or a horizontal antenna) having a plurality of turns is positioned adjacent to the first section 120 of the chamber top 118. In addition, a helical coil RF antenna 128 (sometimes called a helical antenna or a vertical antenna) having a plurality of turns surrounds the second section 122 of the chamber top 118.

In some embodiments, at least one of the planar coil RF antenna 126 and the helical coil RF antenna 128 is terminated with a capacitor 129 that reduces the effective antenna coil voltage. The term “effective antenna coil voltage” is defined herein to mean the voltage drop across the RF antennas 126, 128. In other words, the effective coil voltage is the voltage “seen by the ions,” or equivalently, the voltage experienced by the ions in the plasma.

Also, in some embodiments, at least one of the planar coil RF antenna 126 and the helical coil RF antenna 128 includes a dielectric layer 134 that has a relatively low dielectric constant compared to the dielectric constant of the Al₂O₃ dielectric window material. The relatively low dielectric constant dielectric layer 134 effectively forms a capacitive voltage divider that also reduces the effective antenna coil voltage. In addition, in some embodiments, at least one of the planar coil RF antenna 126 and the helical coil RF antenna 128 includes a Faraday shield 136 that also reduces the effective antenna coil voltage.

A RF source 130, such as a RF power supply, is electrically connected to at least one of the planar coil RF antenna 126 and helical coil RF antenna 128. In many embodiments, the RF power source 130 is coupled to the RF antennas 126, 128 with an impedance matching network 132 that matches the output impedance of the RF source 130 to the impedance of the RF antennas 126, 128 in order to maximize the power transferred from the RF source 130 to the RF antennas 126, 128. Dashed lines from the output of the impedance matching network 132 to the planar coil RF antenna 126 and to the helical coil RF antenna 128 are shown to indicate that electrical connections can be made from the output of the impedance matching network 132 to either or both of the planar coil RF antenna 126 and the helical coil RF antenna 128.

An input of a controller or processor 170 is electrically connected to a sensing output of the RF source 130. The RF source 130 generates signals at the sensing output which are related to certain characteristics of the RF signal generated by the RF source 130. For example, in some embodiments, the RF source 130 generates signals at the sensing output that are related to the voltage, current, and phase of the RF signal generated by the RF source 130. The processor 170 receives the signals from the sensing output of the RF Source 130 and then processes the signals according to the methods of the present invention. In other embodiments, an input of the processor 170 is directly connected to the output of the RF source 130 so that it receives at least a portion of the signal generated by the RF source 130. In this embodiment the processor 170 determines parameters, such as the voltage, current, and phase directly from the RF signal.

In some embodiments, at least one of the planar coil RF antenna 126 and the helical coil RF antenna 128 is formed such that it can be liquid cooled. Cooling at least one of the planar coil RF antenna 126 and the helical coil RF antenna 128 will reduce temperature gradients caused by the RF power propagating in the RF antennas 126, 128. The helical coil RF antenna 128 can include a shunt 129 that reduces the number of turns in the coil.

In some embodiments, the plasma source 101 includes a plasma igniter 138. Numerous types of plasma igniters can be used with the plasma source 101. In one embodiment, the plasma igniter 138 includes a reservoir 140 of strike gas, which is a highly-ionizable gas, such as argon (Ar), which assists in igniting the plasma. The reservoir 140 is coupled to the plasma chamber 102 with a high conductance gas connection. A burst valve 142 isolates the reservoir 140 from the process chamber 102. In another embodiment, a strike gas source is plumbed directly to the burst valve 142 using a low conductance gas connection. In some embodiments, a portion of the reservoir 140 is separated by a limited conductance orifice or metering valve that provides a steady flow rate of strike gas after the initial high-flow-rate burst.

A platen 144 is positioned in the process chamber 102 a height below the top section 118 of the plasma source 101. The platen 144 holds a target, which is referred to herein as the substrate 146, for plasma doping. In the embodiment shown in FIG. 1, the platen 144 is parallel to the plasma source 101. However, the platen 144 can also be tilted with respect to the plasma source 101. In some embodiments, the platen 144 is mechanically coupled to a movable stage that translates, scans, or oscillates the substrate 146 in at least one direction. In one embodiment, the movable stage is a dither generator or an oscillator that dithers or oscillates the substrate 146. The translation, dithering, and/or oscillation motions can reduce or eliminate shadowing effects and can improve the uniformity and conformality of the ion beam flux impacting the surface of the substrate 146.

In many embodiments, the substrate 146 is electrically connected to the platen 144. An output of a bias voltage power supply 148 is electrically connected to the platen 144. The bias voltage power supply 148 generates a bias voltage that biases the platen 144 and the substrate 146 so that dopant ions in the plasma are extracted from the plasma and impact the substrate 146. The bias voltage power supply 148 can be a DC power supply, a pulsed power supply, or a RF power supply.

An input of the processor 170 is electrically connected to a sensing output of the bias voltage power supply 148. The bias voltage power supply 148 generates signals at the sensing output which are related to certain characteristics of the bias voltage signal generated by the bias voltage power supply 148. For example, in some embodiments, the bias voltage power supply 148 generates signals at the sensing output that are related to the voltage, current, pulse repetition rate, and duty cycle of the bias voltage signal generated by the bias voltage power supply 148. The processor 170 receives the signals from the sensing output of the bias voltage power supply 148 and processes the signals according to the methods of the present invention. In other embodiments, an input of the processor 170 is directly connected to the output of the bias voltage power supply 148 or to the platen 144 so that it receives the signal generated by the bias voltage power supply 148. In this embodiment, the processor 170 determines parameters, such as the voltage, current, pulse repetition rate, and duty cycle directly from the bias voltage signal.

The plasma doping system 100 includes various sensors that take measurements related to the stability and repeatability of the plasma doping process. The plasma doping system 100 includes a Faraday dosimeter 172 or other type of sensor that directly measures the dose of ions received by the substrate 146. The Faraday dosimeter 172 can be located on the platen 144 proximate to the substrate 146.

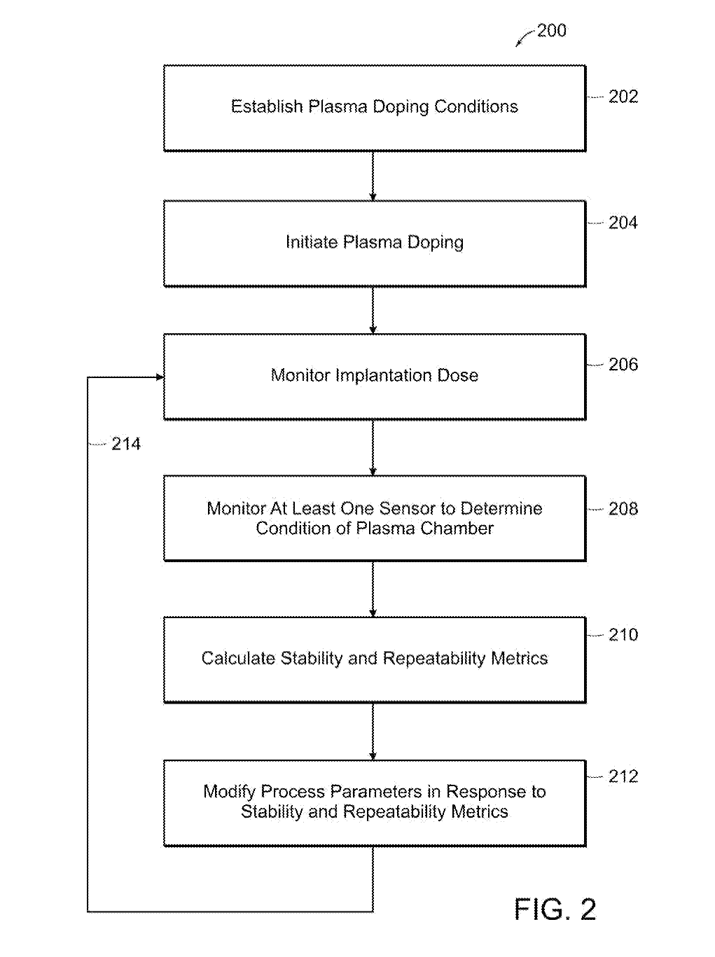

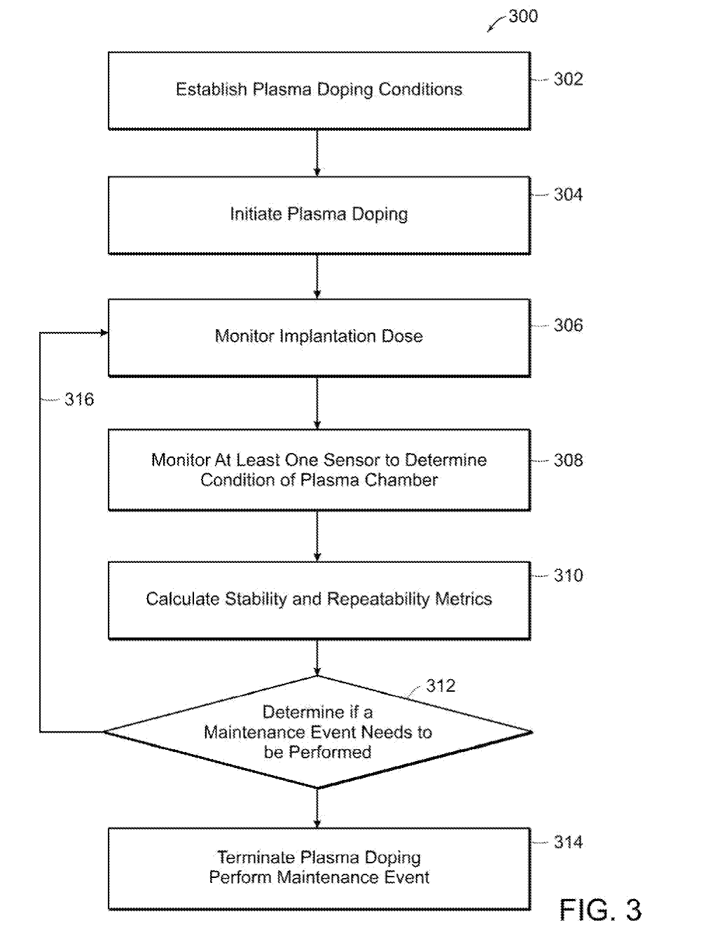

In addition, the plasma doping system 100 includes at least one sensor that measures properties of the plasma which indicate the conditions of the plasma chamber 102. In many embodiments, the at least one sensor performs real time in-situ measurements of plasma conditions. In some embodiments, the plasma doping system 100 includes an optical emission sensor 174 that detects optical emission from the plasma. The optical emission sensor 174 can determine plasma parameters, such as the type of ions, the ionization fraction and the density of ions in the plasma. Measurements of such plasma parameters can indicate the conditions of the plasma chamber 102. An output of the optical emission sensor 174 can be electrically connected to an input of the processor 170 so that the processor 170 can use the data from the optical emission sensor 174 in the methods of the present invention to take a corrective action and/or to trigger a maintenance event as described in connection with FIGS. 2 and 3.

In some embodiments, the plasma doping system 100 includes a residual gas analyzer 176, which is a type of mass spectrometer that measures trace gases in a low pressure environment. Measurements from the residual gas analyzer 176 can also indicate the conditions of the plasma chamber 102. Also, in some embodiments, the plasma doping system 100 includes electrical sensors 178 that directly measure electrical characteristics of the plasma, such as the plasma floating potential. Outputs of the electrical sensors 178 can be electrically connected to inputs of the processor 170 so that the processor 170 can use the data from the electrical sensors 178 in the methods of the present invention to take a corrective action and/or to trigger a maintenance event as described in connection with FIGS. 2 and 3.

Some embodiments of the plasma doping system 100 include a means to generate neutrals for conformal doping or other applications. In some embodiments, the plasma doping system 100 includes a temperature controller that is used to control the temperature of the platen 144 and the temperature of the substrate 146. The temperature controller is designed to maintain the temperature of the substrate 146 at a relatively low temperature that is sufficient for absorption of a film layer that generates neutrals during film desorption according to the present invention. Also, in some embodiments, the plasma doping system 100 includes a separate neutral source that is positioned proximate to the substrate 146. Also, in some embodiments, the plasma doping system 100 includes a nozzle that injects a controlled amount of gas to absorb a film layer at predetermined times relative to bias voltage pulses generated by the bias voltage power supply 148 in order to enhance re-absorption of the film layer on the substrate 146. Also, in some embodiments, the plasma doping system 100 includes a radiation source that provides a burst or pulse of radiation that rapidly desorbs an absorbed film on the substrate 146. A plasma doping system with such features is described in U.S. patent application Ser. No. 11/774,587, filed Jul. 7, 2007 entitled “Conformal Doping Using High Neutral Density Plasma Implant.” The entire specification of U.S. patent application Ser. No. 11/774,587 is incorporated herein by reference.

One skilled in the art will appreciate that the there are many different possible variations of the plasma doping system 100 that can be used with the features of the present invention. See, for example, the descriptions of the plasma doping system in U.S. patent application Ser. No. 10/908,009, filed Apr. 25, 2005, entitled “Tilted Plasma Doping.” Also, see the descriptions of the plasma doping system in U.S. patent application Ser. No. 11/163,303, filed Oct. 13, 2005, entitled “Conformal Doping Apparatus and Method.” Also, see the descriptions of the plasma doping system in U.S. patent application Ser. No. 11/163,307, filed Oct. 13, 2005, entitled “Conformal Doping Apparatus and Method.” Also, see the descriptions of the plasma doping system in U.S. patent application Ser. No. 11/566,418, filed Dec. 4, 2006, entitled “Plasma Doping with Electronically Controllable implant Angle.” Also, see the descriptions of the plasma doping system in U.S. patent application Ser. No. 11/617,785, filed Dec. 29, 2006, entitled “Plasma Immersion Ion Source with Low Effective Antenna Voltage.” Also, see the descriptions of the plasma doping system in U.S. patent application Ser. No. 11/623,739, filed Jan. 16, 2007, entitled “Liner for Plasma Doping Apparatus with Reduced Metal Contamination.” Also, see the descriptions of the plasma doping system in U.S. patent application Ser. No. 11/676,069, filed Feb. 16, 2007, entitled “Multi-Step Plasma Doping with Improved Dose Control. Also, see the descriptions of the plasma doping system in U.S. patent application Ser. No. 11/678,524, filed Feb. 23, 2007, entitled “Technique For Monitoring and Controlling A Plasma Process.” Also, see the descriptions of the plasma doping system in U.S. patent application Ser. No. 11/687,822, filed Mar. 19, 2007 entitled “Method Of Plasma Process With In-Situ Monitoring and Process Parameter Tuning. Also, see the descriptions of the plasma doping system in U.S. patent application Ser. No. 11/771,190, filed Jun. 29, 2007, entitled “Plasma Doping with Enhanced Charge Neutralization.” In addition, see the descriptions of the plasma doping system in U.S. patent application Ser. No. 11/774,587, filed Jul. 7, 2007 entitled “Conformal Doping Using High Neutral Density Plasma Implant.” The entire specifications of these patent applications are incorporated herein by reference.

In operation, the RF source 130 generates an RF current that propagates in at least one of the RF antennas 126 and 128. That is, at least one of the planar coil RF antenna 126 and the helical coil RF antenna 128 is an active antenna. The term “active antenna” is herein defined as an antenna that is driven directly by a power supply. In some embodiments of the plasma doping apparatus of the present invention, the RF source 130 operates in a pulsed mode. However, the RF source can also operate in the continuous mode.

In some embodiments, one of the planar coil antenna 126 and the helical coil antenna 128 is a parasitic antenna. The term “parasitic antenna” is defined herein to mean an antenna that is in electromagnetic communication with an active antenna, but that is not directly connected to a power supply. In other words, a parasitic antenna is not directly excited by a power supply, but rather is excited by an active antenna positioned in electromagnetic communication with the parasitic antenna. In the embodiment shown in FIG. 1, the active antenna is one of the planar coil antenna 126 and the helical coil antenna 128 powered by the RF source 130. In some embodiments of the invention, one end of the parasitic antenna is electrically connected to ground potential in order to provide antenna tuning capabilities. In this embodiment, the parasitic antenna includes the coil adjuster 129 that is used to change the effective number of turns in the parasitic antenna coil. Numerous different types of coil adjusters, such as a metal short, can be used.

The RF currents in the RF antennas 126, 128 then induce RF currents into the chamber 102. The RF currents in the chamber 102 excite and ionize the process gas so as to generate a plasma in the chamber 102. The plasma chamber liner 125 shields metal sputtered by ions in the plasma from reaching the substrate 146.

The bias voltage power supply 148 biases the substrate 146 with a negative voltage that attracts ions in the plasma towards the substrate 146. During the negative voltage pulses, the electric field within the plasma sheath accelerates ions toward the substrate 146 which implants the ions into the surface of the substrate 146. A process of absorbing a film layer and then rapidly desorbing the film layer to generate neutrals that scatter ions for ion implantation can be used to enhance the conformality of the plasma doping as described in U.S. patent application Ser. No. 11/774,587, filed Jul. 7, 2007 entitled “Conformal Doping Using High Neutral Density Plasma Implant.”

Signals from the various sensors that take measurements related to the stability and repeatability of the plasma doping process are sent to the processor 170, where they are analyzed by the methods of the present invention. In particular, the Faraday dosimeter 172 measures the dose of the ion implantation flux and sends a signal to the processor 170. Also, at least one sensor performs real time in-situ measurements of plasma conditions. In various embodiments, at least one of the optical emission sensor 174, the residual gas analyzer 176, and various the electrical sensors 178 send data to the processor 170 that relates to the conditions of the plasma chamber 102. The processor 170 implements the methods of the present invention to analyze the data, calculate stability and repeatability metrics, and then to take an appropriate corrective action and/or to trigger a maintenance event, if necessary, as described in connection with FIGS. 2 and 3. Thus, the methods and apparatus of the present invention improve process control and process repeatability of the plasma doping process by monitoring electrical signals directly related to the implant dose generated by the plasma and to the chamber conditions and then perform an appropriate corrective action and/or to trigger a maintenance event in response to the monitoring.

FIG. 2 illustrates a flow chart 200 of a method of in-situ monitoring and process control of a plasma doping process according to the present invention. Referring to both FIG. 1 and FIG. 2, in a first step 202, the plasma doping conditions are established. The first step 202 includes performing any necessary pre-cleaning steps and also performing steps required to establish stable plasma doping conditions. In a second step 204, the plasma doping process is initiated. In the second step 204 the target or substrate 146 is exposed to ion implantation flux and then biased with the bias voltage power supply 148. In a third step 206, the ion implantation dose is monitored with the Faraday dosimeter 172.

In a fourth step 208, at least one sensor is monitored to determine electrical signals which indicate the condition of the plasma chamber 102. There are numerous types of sensors that can be monitored to determine the condition of the plasma chamber 102, only some of which are described herein. In various embodiments, electrical sensors are used to monitor signals generated with the RF source 130. One type of sensor is an electrical sensor built into or in electrical communication with the RF source 130 that generates electrical monitoring signals, such as the signals generated by the sensor output of the RF source 130. For example, such sensors can measure the current, voltage, and phase of the RF signal generated by the RF source. Other sensors can be used to measure the current flowing through the RF antenna coils 126, 128, the RF impedance of the antenna coils 126, 128, and the self bias or voltage developed on the antenna coils 126, 128. Plasma chamber conditions can be determined from these electrical measurements.

Also, in various embodiments, electrical signals applied to the substrate 146 are monitored during plasma doping. There are numerous types of sensors that can be used in accordance with this method to determine the condition of the plasma chamber 102. One type of sensor is an electrical sensor built into or in electrical communication with the bias voltage power supply 148 that generates electrical monitoring signals, such as the signals generated by the sensor output of the bias voltage power supply 148 which measures the voltage, current, pulse repetition rate, and duty cycle of pulses generated by the bias voltage power supply 148. Another type of sensor is an electrical sensor which is in electrical communication with the platen 144 supporting the substrate 146. Such a sensor can measure current flowing through the platen 144 and the substrate 146 and the voltage applied to the platen 144 and the substrate 146 during the pulses. Chamber conditions can also be determined from these electrical measurements.

Also, in various embodiments, the at least one electrical sensor monitors signals associated with the plasma itself. There are numerous types of sensors that can be used in accordance with this method to determine the condition of the plasma chamber 102. In these embodiments, at least one sensor measures various plasma characteristics, such as the plasma floating potential, the potential developed on the plasma chamber 102 walls, and secondary electron emission. Plasma chamber conditions can also be determined from these electrical measurements.

In a fifth step 210, stability and repeatability metrics are determined from the measured ion implantation dose and from the at least one electrical sensor monitoring signal that indicates the condition of the plasma chamber 102. For example, in one specific embodiment, the ion implantation dose per pulse applied to the substrate 146 is determined. The ion implantation dose per pulse has been found to be a good metric for monitoring the stability and repeatability of a plasma doping process. Also, the plasma impedance can be determined from measurements of the electrical sensor monitoring signals. The stability and repeatability metrics can also be a direct sensor measurement signal.

In the sixth step 212, the process parameters are changed, if necessary, in response to the stability and repeatability metrics. For example, in various embodiments, the process parameters can be at least one of the chamber pressure, the process gas flow rates, the RF power, the RF voltage, the pulse repetition rate, and the duty cycle of the bias voltage waveform applied to the substrate 146. Any other process parameter can be used with the method described in connection with FIG. 2.

In the seventh step 214, the third step 206, the fourth step 208, and the fifth step 210 are then repeated until the plasma doping process is terminated. That is, the ion implantation dose and the at least one sensor which indicates the condition of the plasma chamber 102 are monitored, the stability and repeatability metrics are determined, and the process parameters are changed in response to the newly determined stability and repeatability metrics.

FIG. 3 illustrates a flow chart 300 of a method of in-situ monitoring of a plasma doping process that triggers a maintenance event and or termination of the plasma doping process according to the present invention. The method is similar to the method described in connection with FIG. 2. However, stability and repeatability metrics trigger a maintenance event, which may also include termination of the plasma doping process. Referring to both FIG. 1 and FIG. 3 and to the description of FIG. 2, in a first step 302, the plasma doping conditions are established. In a second step 304, the plasma doping process is initiated. In a third step 306, the ion implantation dose is monitored with the Faraday dosimeter 172.

In a fourth step 308, at least one sensor is monitored to determine electrical signals which indicate the condition of the plasma chamber 102 as described herein. The fourth step 308 includes monitoring at least one of many possible sensors. In various embodiments, the fourth step 308 can include monitoring electrical signals generated by the RF source 130 and/or monitoring electrical signals applied to the substrate 146 during plasma doping. In addition, the fourth step 308 can include monitoring signals associated with the plasma itself. In a fifth step 310, stability and repeatability metrics are determined from the measured ion implantation dose and from the at least one electrical sensor monitoring signals which indicates the condition of the plasma chamber 102 as described herein.

In the sixth step 312, the stability and repeatability metrics are calculate and then analyzed to determine if a maintenance event should be performed. In a seventh step 314, the maintenance event is performed if it was determined in the sixth step 312 that the maintenance event is necessary. The maintenance event can be any type of maintenance event and can be any number of individual maintenance events. The plasma doping process is typically terminated when maintenance events are performed. However, the methods and apparatus of the present invention can be used whether or not the plasma doping process is terminated. In an eighth step 316, the third step 306, the fourth step 308, the fifth step 310, and the sixth step 312 are repeated sequentially. The methods described in connection with FIGS. 2 and 3 can greatly improve process control and process repeatability of a plasma doping process.

### Equivalents

While the present teachings are described in conjunction with various embodiments and examples, it is not intended that the present teachings be limited to such embodiments. On the contrary, the present teachings encompass various alternatives, modifications and equivalents, as will be appreciated by those of skill in the art, may be made therein without departing from the spirit and scope of the invention.

What is claimed is:

1. A method of in-situ monitoring of a plasma doping process, the method comprising:
a. generating a plasma in a plasma chamber proximate to a platen supporting a substrate, the plasma comprising dopant ions;
b. biasing the platen with a bias voltage waveform having a negative potential that attracts ions in the plasma to the substrate for plasma doping;
c. measuring a dose of ions attracted to the substrate;
d. performing at least one sensor measurement to determine the condition of the plasma chamber; and
e. modifying at least one plasma process parameter in response to the measured dose and in response to the at least one sensor measurement.

2. The method of claim 1 wherein the measuring the dose of ions attracted to the substrate comprises determining a dose per bias voltage waveform pulse.

3. The method of claim 1 wherein the performing at least one sensor measurement comprises performing optical emission measurements of the plasma.

4. The method of claim 1 wherein the performing at least one sensor measurement comprises performing residual gas analysis measurements.

5. The method of claim 1 wherein the performing at least one sensor measurement comprises measuring a plasma floating potential of the plasma.

6. The method of claim 1 wherein the performing at least one sensor measurement comprises performing a measurement of at least one of an RF antenna impedance and an RF antenna self bias.

7. The method of claim 1 wherein the performing at least one sensor measurement comprises performing a measurement of at least one of current, voltage, and phase of an RF signal used for generating the plasma.

8. The method of claim 1 wherein the modifying the at least one plasma process parameter comprises modifying at least one of a chamber pressure and a process gas flow rate.

9. The method of claim 1 wherein the modifying the at least one plasma process parameter comprises modifying at least one of an RF power and an RF voltage used for generating the plasma.

10. The method of claim 1 wherein the modifying the at least one plasma process parameter comprises modifying at least one of a voltage, a duty cycle, and a pulse repetition rate of the bias voltage waveform.

11. A method of in-situ monitoring of a plasma doping process, the method comprising:
a. generating a plasma in a plasma chamber proximate to a platen supporting a substrate, the plasma comprising dopant ions;
b. biasing the platen with a bias voltage waveform having a negative potential that attracts ions in the plasma to the substrate for plasma doping;
c. measuring a dose of ions attracted to the substrate;
d. performing at least one sensor measurement to determine the condition of the plasma chamber; and
e. determining whether a maintenance event needs to be performed in response to the measured dose of ions and in response to the at least one sensor measurement.

12. The method of claim 11 wherein the measuring the dose of ions attracted to the substrate comprises determining a dose per bias voltage waveform pulse.

13. The method of claim 11 wherein the performing at least one sensor measurement comprises performing optical emission measurements of the plasma.

14. The method of claim 11 wherein the performing at least one sensor measurement comprises performing residual gas analysis measurements.

15. The method of claim 11 wherein the performing at least one sensor measurement comprises measuring a plasma floating potential of the plasma.

16. The method of claim 11 wherein the performing at least one sensor measurement comprises performing a measurement of at least one of a current, a voltage, and a phase of an RF signal used for generating the plasma.

17. The method of claim 11 wherein the performing at least one sensor measurement comprises performing a measurement of at least one of an RF antenna impedance and an RF antenna self bias.

18. The method of claim 11 wherein the modifying the at least one plasma process parameter comprises modifying at least one of a chamber pressure and a process gas flow rate.

19. The method of claim 11 wherein the modifying the at least one plasma process parameter comprises modifying at least one of an RF power and an RF voltage used for generating the plasma.

20. The method of claim 11 wherein the modifying the at least one plasma process parameter comprises modifying at least one of a voltage, a duty cycle, and a pulse repetition rate of the bias voltage waveform.

21. A plasma doping apparatus comprising:
a. a chamber for containing a process gas;
b. a plasma source that generates a plasma from the process gas;
c. a platen that supports a substrate proximate to the plasma source for plasma doping;
d. a dosimeter that is positioned in the chamber to measure a dose of ions impacting the substrate;
e. a bias voltage power supply having an output that is electrically connected to the platen, the bias voltage power supply generating a bias voltage waveform with a negative potential that attracts ions in the plasma to the substrate for plasma doping;
f. at least one sensor for measuring conditions of the plasma chamber; and
g. a processor having an input electrically connected to the at least one sensor and an output that is electrically connected to at least one of the plasma source, the bias voltage power supply, and a process gas controller, the processor generating a signal in response to a measurement from the dosimeter and in response to the at least one sensor that improves at least one of stability and repeatability of the plasma doping.

22. The plasma doping apparatus of claim 21 wherein the at least one sensor comprises an electron detector that measures secondary electron emission.

23. The plasma doping apparatus of claim 21 wherein the at least one sensor comprises at least one of an optical emission spectrometer and a residual gas analyzer.

24. The plasma doping apparatus of claim 21 wherein the at least one sensor comprises a sensor that measures at least one of RF antenna self bias and RF impedance.

25. The plasma doping apparatus of claim 21 wherein the at least one sensor comprises a sensor that measures at least one of current, voltage, and phase of an RF signal generated by the RF source.
